(19) United States
(12) Patent Application Publication
(10) Pub. No.: US 2005/0081787 A1
(43) Pub. Date: Apr. 21, 2005

(54) Apparatus and method for supplying a source, and method of depositing an atomic layer using the same

(76) Inventors: Ki-Vin Im, Gyeonggi-do (KR); Sung-Tae Kim, Seoul (KR); Young-Sun Kim, Suwon-Si (KR); Gab-Jin Nam, Gyeonggi-do (KR); In-Sung Park, Seoul (KR); Eun-Ae Chung, Gyeonggi-do (KR); Ki-Yeon Park, Gyeonggi-do (KR); Seung-Hwan Lee, Seoul (KR)

Correspondence Address: Robert W. Glatz;Myers Bigel Sibley & Sajovec, Post Office Box 37428, Raleigh, NC, 27627, US

(21) Appl. No.: 10/951,937

(22) Filed: Sep. 28, 2004

(30) Foreign Application Priority Data
Oct. 15, 2003 (KR) 10-2003-71811

(51) Int. Cl. C23C 16/00

(52) U.S. Cl. 118/715

(57) ABSTRACT

Methods of supplying a source to a reactor include charging a gaseous source into a charging volume by selectively activating a source charger coupled between the charging volume and a source reservoir. The gaseous source is then supplied from the charging volume into a deposition process reactor by selectively activating a source supplier coupled between the charging volume and the reactor after the gaseous source in the charging volume attains a desired internal pressure. Apparatus for supplying a source and methods and apparatus for depositing an atomic layer are also provided.

### CROSS-REFERENCE TO RELATED APPLICATIONS

This application is related to and claims priority from Korean Patent Application No. 2003-71811 filed on Oct. 15, 2003, the disclosure of which is hereby incorporated herein by reference in its entirety.

### BACKGROUND OF THE INVENTION

The present invention relates to an apparatus and method for providing a source material and, more particularly, to supplying a source material to a deposition process reactor.

Atomic layer deposition (ALD) is a kind of thin layer deposition technique generally using chemisorption and desorption characteristics of gas molecules to deposit layers in fabrication of integrated circuit devices. Each reactant is typically supplied to a processing chamber sequentially in a predetermined order, and a monoatomic layer is deposited on a semiconductor substrate based on a surface reaction, such as chemisorption and/or desorption.

In contrast to a conventional chemical vapor deposition (CVD) process, the reactant in the ALD process reacts in a manner providing a self-limiting mechanism, so that chemical elements of the source generally react only to the surface of the substrate and not with each other. Therefore, the ALD process may be advantageous for accurate control of layer composition, limited or no generation of particles, potentially excellent step coverage in depositing a large area thin layer and accurate control of the layer thickness. In addition, the thin layer deposited by the ALD process may be even more advantageous as the design rule for various integrated circuit (semiconductor) devices is reduced.

One of the relevant factors for depositing a thin layer by ALD, such as an oxide layer coated on a surface of the semiconductor device, is maintaining a sufficient supply of the source. When insufficient source is supplied during the ALD process, there may be a problem in that the step coverage of the thin layer may be deteriorated. Therefore, various solutions for sufficiently supplying the source have been suggested so as to reduce problems with poor step coverage. For example, a temperature of the source may be raised to increase a flow rate of the source or a supplying time for the source may be increased.

However, when the temperature of the source is raised in the ALD process, the changed process conditions may result in the deposited thin layer not providing the same layer characteristics as a layer deposited without raising the temperature. In addition, raising the source temperature and maintaining a high source temperature typically require additional apparatus in fabricating the semiconductor device. As such, the productivity and reliability of the semiconductor device fabricating apparatus may be decreased. When the supplying time is increased in the ALD process, the deposition time for depositing a layer of a predetermined thickness is increased, which may also decrease the productivity of the deposition process.

To address the above-mentioned problems, Korean Patent Laid Open Publication No. 2002-74708 discloses an apparatus for increasing the amount of the source supplied to a reactor in which the atomic layer is deposited. The apparatus disclosed in the above Korean Patent Laid Open Publication includes a gas container from which the gas is discontinuously discharged sequentially, a processing chamber in which a thin layer is deposited on a semiconductor substrate, a gas flow controller for controlling the amount of the gas flowing through a gas line from the gas container to the processing chamber, a front valve disposed on the gas line between the gas container and the gas flow controller and a rear valve disposed on the gas line between the gas flow controller and the processing chamber.

The apparatus disclosed in the above Korean Patent Laid Open Publication provides for charging of the gas in the gas line between the front valve and the gas flow controller and between the gas flow controller and the rear valve by opening the front valve and closing the rear valve, and the gas is supplied into the processing chamber by opening the front and rear valves. Therefore, in an apparatus for fabricating a semiconductor device by discontinuously supplying the gas sequentially, such as the atomic layer deposition process or the periodic chemical vapor deposition process, there may be an advantage in that the amount of the supplied gas may be increased over the maximum value preset at the gas flow controller without changing the temperature and supply time of the gas.

However, the apparatus disclosed in the above Korean Patent Laid Open Publication may still be limited in that the gas is absorbed into the inner surface of the gas line while the gas passes through the gas line, thereby decreasing the supplying efficiency of the gas.

FIG. 1 is a view schematically illustrating a first conventional apparatus for supplying the source. As shown in FIG. 1, the first conventional apparatus for supplying the source includes a source reservoir 10 for containing a liquid source 12 and a gaseous source 14 vaporized from the liquid source 12 and a source supplier 20 connecting the source reservoir 10 to a reactor 30, in which a mono-layer is formed by the ALD process.

The source supplier 20 includes a pressure regulator 21, such as a valve, and a supplying line 23. The supplying line 23 usually has a length ranging from a few meters to about ten meters, and the source is generally absorbed onto an inner surface of the supplying line 23 while passing through the supplying line 23 from the source reservoir 10 to the reactor 30. As a result, the supplying efficiency of the source may be reduced. The above-mentioned inner absorption of the source may be particularly serious when the source is an organic metal compound of high molecular weight and low vapor pressure, such as tetrakis ethylmethylamino hafnium (TEMAH). TEMAH may be used for depositing a hafnium oxide (HfO₂) layer, which type of layer has recently been of interest for various applications. As such a length of the supplying line may need to be shortened so that sufficient source is supplied without adjusting the time and temperature of the process and without the inner absorption of the source.

FIG. 2A is a view schematically illustrating a second conventional apparatus for supplying the source. Referring to FIG. 2A, a source reservoir 50 including a liquid source 52 and a gaseous source 54 is disposed on a reactor 70 in which a mono-atomic layer is formed by the ALD process. The source 54 is supplied to the reactor 70 through a source supplier 60 including a pressure regulator 61 and a supplying line 63. According to the second conventional apparatus for supplying the source, the source reservoir 50 is installed adjacent to the reactor 70 and, thus, the length of the supplying line 63 can be minimized. As a result, the inner absorption of the source may be reduced or even prevented, and the source may be sufficiently supplied in a short time. However, the second conventional apparatus for supplying the source shown in FIG. 2A may have a problem that the supplying line 63 may be contaminated by the liquid source 52.

FIG. 2B is a view schematically illustrating the second conventional apparatus shown in FIG. 2A when the reactor is opened. As shown in FIG. 2B, when the reactor 70 is opened, the liquid source 52 may unexpectedly flow through the supplying line 63 and cause various impurities, such as particles. Therefore, the second conventional apparatus shown in FIGS. 2A and 2B may require periodic removal of the impurities on the supplying line 63 and in the reactor 70, which may increase the maintenance cost of the apparatus.

Therefore, there is a need for improved apparatus for supplying the source in an ALD process, which may sufficiently supply the source into the reactor by shortening the supplying line with facilitating the maintenance thereof.

### SUMMARY OF THE INVENTION

Embodiments of the present invention include apparatus for supplying a source, the apparatus including a charging volume. A source supplier connected to the charging volume is configured to selectively couple the charging volume to a deposition process reactor. A source charger connected to the charging volume is configured to selectively couple the charging volume to a gaseous source.

In other embodiments of the present invention, a source reservoir is provided that is configured to hold the gaseous source. The source may have a gaseous state and a liquid state and the source reservoir may include a source vaporizer that vaporizes the source from the liquid state to the gaseous state to provide the gaseous source. The source vaporizer may be a bubbler. The source reservoir may include a liquid reservoir for source in the liquid state and a gaseous reservoir for source in the gaseous state.

In some embodiments of the present invention, the charging volume is a charging line having a volume selected based on a type of the source and a process to be performed in the deposition process reactor. The charging volume may be a charging vessel positioned proximate the deposition process reactor.

In further embodiments of the present invention, the source is a precursor compound of metal alkoxide, the metal alkoxide including at least one of hafnium (Hf), tantalum (Ta), aluminum (Al), silicon (Si), lanthanum (La), yttrium (Y), zirconium (Zr), magnesium (Mg), strontium (Sr), lead (Pb), titanium (Ti), niobium (Nb), cerium (Ce), ruthenium (Ru), barium (Ba), calcium (Ca), Indium (In), germanium (Ge), tin (Sn), vanadium (V), arsenic (As), praseodymium (Pr), antimony (Sb) and/or phosphorous (P). The source may include at least one of tetrakis ethylmethylamino hafnium (TEMAH), Hf(OEt)₄, Hf(OPr)₃, Hf(OBu)₄, tetra n-butoxy hafnium (Hf(OnBu)₄), tetra tert-butoxy hafnium (Hf(OtBu)₄), Tetrakis-(mmp) hafnium (Hf(mmp)₄), Hf(OtBu)₂(dmae)₂ and/or Hf(OtBu)₂(mmp)₂, wherein ‘dmae’ indicates dimethylaminoethoxide (—OC₂H₄N(CH₃)₂) and ‘mmp’ indicates 1-methoxy-2-methyl-2propoxy (—OC₄H₈OCH₃).

In other embodiments of the present invention, the source charger includes a charging line connecting the source reservoir and the charging volume and a charging valve coupled to the charging line and having an open state allowing source to flow from the source reservoir to the charging volume and a closed state restricting flow of source from the source reservoir to the charging volume. A controller is configured to selectively activate the charging valve to control a pressure of the gaseous source charged into the charging vessel. The charging valve may be a pneumatic valve or a throttle valve. The deposition process reactor may be an atomic layer deposition (ALD) process reactor or a chemical vapor deposition (CVD) process reactor. The charging volume may have a size selected to be inversely proportional to a partial pressure of the source and the partial pressure of the source may be defined as a fractional pressure of the source in a source mixture including the source.

In further embodiments of the present invention, the source supplier includes a supplying line that connects the charging volume to the reactor and a supplying valve coupled to the charging volume and having an open state allowing source to flow from the charging volume to the reactor and a closed state restricting flow of source from the charging volume to the reactor. A controller is configured to selectively activate the supplying valve to control an amount of the source supplied to the reactor through the supplying line. The supplying valve may be a pneumatic valve or a throttle valve. The controller may be configured to charge the gaseous source into the charging volume to a desired pressure while the supplying valve is closed. The apparatus may also include a purging member configured to purge a residual source remaining in the charging volume.

In other embodiments of the present invention, methods of supplying a source to a reactor include charging a gaseous source into a charging volume by selectively activating a source charger coupled between the charging volume and a source reservoir. The gaseous source is then supplied from the charging volume into a deposition process reactor by selectively activating a source supplier coupled between the charging volume and the reactor after the gaseous source in the charging volume attains a desired internal pressure. The desired internal pressure of the charging volume may be between about 90 Torr and about 100 Torr. Supplying the gaseous source may be followed by removing a residual gaseous source remaining in the charging volume after supplying the gaseous source to the reactor.

In further embodiments of the present invention, methods of depositing an atomic layer include loading a substrate into an atomic layer deposition (ALD) process reactor. A first gaseous source is charged into a charging volume. The first gaseous source is supplied into the reactor from the charging volume so that the first gaseous source is chemisorbed onto a surface of the substrate. A first purge gas is provided into the reactor so that a portion of the first source that is not chemisorbed onto the surface of the substrate is removed from the reactor. A second source is supplied into the reactor after the first purge gas so that the second source is chemisorbed onto the surface of the substrate including the first source. A second purge gas is provided to the reactor so that a portion of the second source that is not chemisorbed onto the surface of the substrate is removed from the reactor. Charging a first gaseous source may include charging the first gaseous source until the charging volume attains a desired internal pressure. The desired internal pressure of the charging volume may be between about 90 Torr and about 100 Torr. Charging a first gaseous source may be preceded by vaporizing a first source in a liquid state into a first source in a gaseous state to provide the first gaseous source.

In other embodiments of the present invention, supplying the first gaseous source into the reactor, providing a first purge gas into the reactor, supplying a second source into the reactor and providing a second purge gas into the reactor may be repeated a selected number of times. Vaporizing a first source and charging a first gaseous source into a charging volume in such embodiments are carried out while providing a first purge gas into the reactor, supplying a second source into the reactor and/or providing a second purge gas into the reactor. The first and second purge gases may be argon (Ar) gas and/or nitrogen (N₂) gas. The second source may be at least one of ozone (O₃), oxygen (O₂), water (H₂O), hydrogen peroxide (H₂O₂), nitrous oxide (N₂O), carbon dioxide (CO₂), ammonia (NH₃), nitrogen (N₂), and/or ozone (O₃), oxygen (O₂), water (H₂O), hydrogen peroxide (H₂O₂), nitrous oxide (N₂O), carbon dioxide (CO₂), ammonia (NH₃), and/or nitrogen (N₂) that are activated by a plasma gas, a remote plasma gas and/or ultraviolet rays.

### BRIEF DESCRIPTION OF THE DRAWINGS

The above and other features and advantages of the present invention will become readily apparent by reference to the following detailed description when considering in conjunction with the accompanying drawings, in which:

FIG. 1 is a schematic view illustrating a first conventional apparatus for supplying a source;

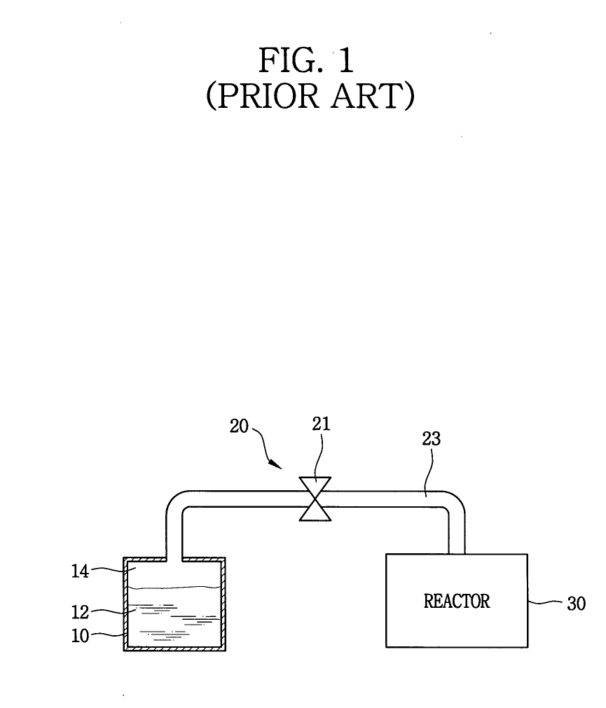

FIG. 2A is a schematic view illustrating a second conventional apparatus for supplying a source;

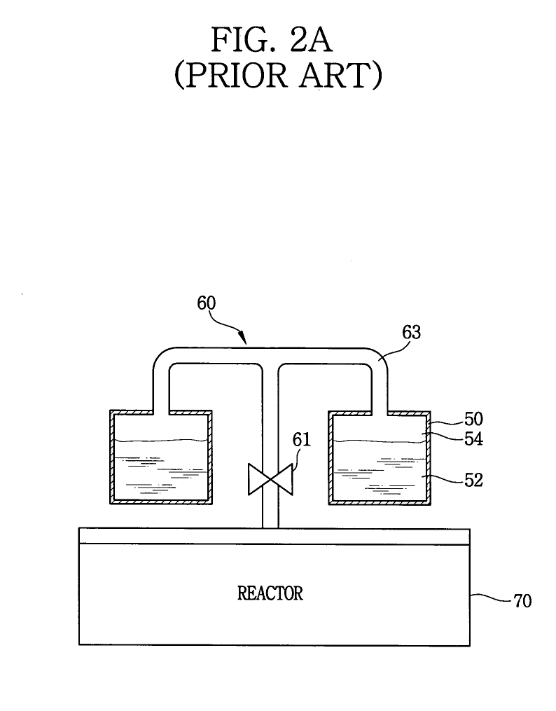

FIG. 2B is a schematic view illustrating the apparatus shown in FIG. 2A when the reactor is opened;

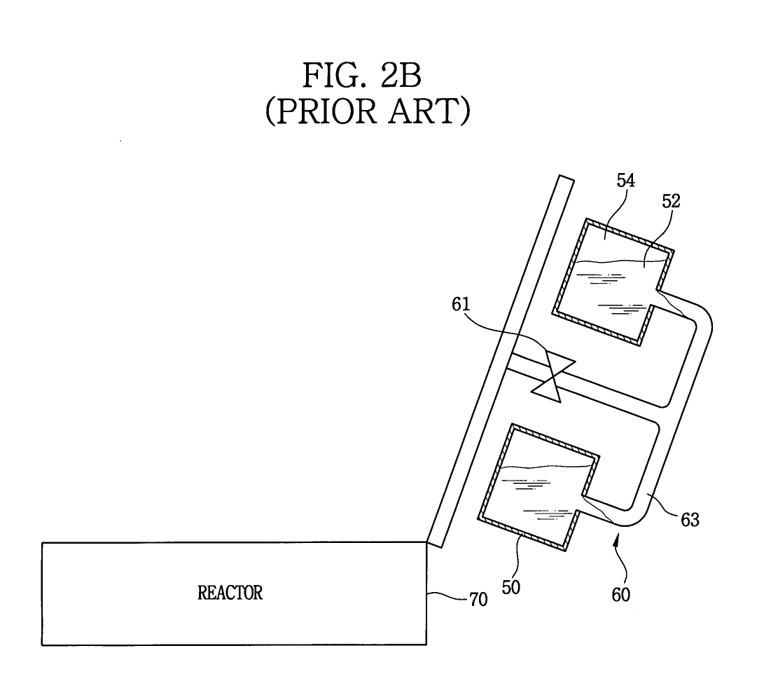

FIG. 3 is a schematic view illustrating a supplying apparatus for supplying a source according to some embodiments of the present invention;

FIG. 4 is a flowchart illustrating a method of supplying a source according to some embodiments of the present invention;

FIG. 5 is a flowchart illustrating methods of depositing an atomic layer according to some embodiments of the present invention;

FIG. 6A is a picture illustrating a cross sectional surface of a hafnium oxide layer deposited under the conditions of Example 1; and

FIG. 6B is a picture illustrating a cross sectional surface of a hafnium oxide layer deposited under the conditions of Example 2.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer: it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

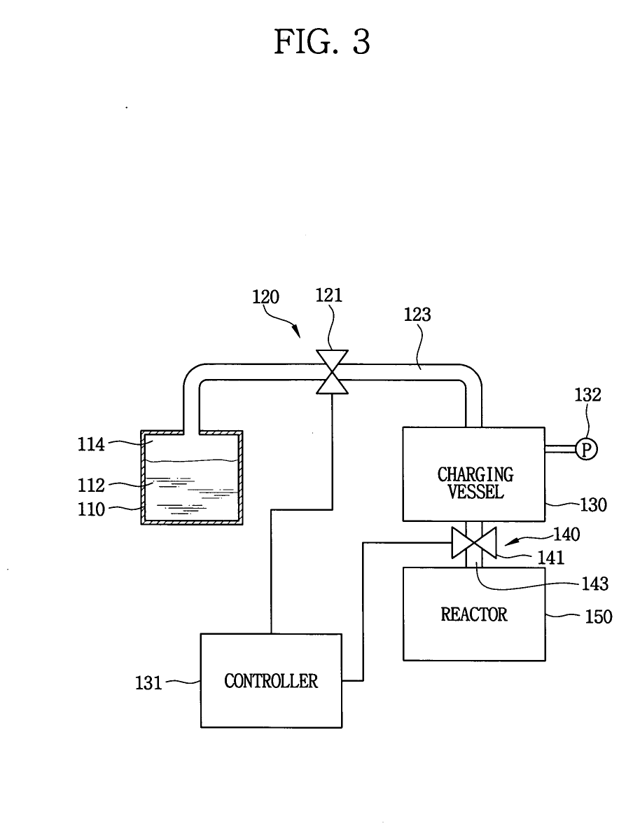

FIG. 3 is a schematic view illustrating a supplying apparatus for supplying a source according to some embodiments of the present invention. As shown in FIG. 3, a supplying apparatus according to the embodiments of FIG. 3 includes a source reservoir 110, a source charger 120, a charging volume, which may be provided by a charging vessel 130, and a source supplier 140. The charging vessel 130 is installed on a supplying line between the source reservoir 110 and a reactor 150 in which an atomic layer is deposited by an ALD process to act as a buffer in supplying the source into the reactor 150. As a result, the source, may be sufficiently supplied into the reactor 150 in a short time.

The source reservoir 110 includes a gaseous source. The source may be used for forming various layers, such as an oxide layer, a nitride layer and/or a metal layer. The supplying apparatus according to the embodiments of FIG. 3 may be particularly efficient when used with a source having a high molecular weight and a low vapor pressure, because it may be difficult to supply such a source to the reactor through the supplying line due to the high molecular weight and low vapor pressure thereof.

Various kinds of sources having a high molecular weight and low vapor pressure are known. Examples of a hafnium source for forming a hafnium oxide layer include tetrakis ethylmethylamino hafnium (TEMAH), tetra tert-butoxy hafnium (Hf(OtBu)₄), Tetrakis-(mmp) hafnium (Hf(mmp)₄), Hf(OtBu)₂(dmae)₂, Hf(OtBu)₂(mmp)₂, tetrakis triethylsiloxy hafnium, Hf(OEt)₄, Hf(OiPr)₄, tetra n-butoxy hafnium (Hf(OnBu)₄), Hf(OtAm)₄, Hf(OPr)₃,Hf(OBu)₄, and the like, wherein ‘dmae’ indicates dimethylaminoethoxide (—OC₂H₄N(CH₃)₂) and ‘mmp’ indicates 1-methoxy-2-methyl-2propoxy (—OC₄H₈OCH₃). Furthermore, Hf(OtBu)₄ indicates Hf[OC₄H₉]₄ and Hf(mmp)₄ indicates Hf[OC₄H₈OCH₃]₄. In addition, Hf(OtBu)₂(dmae)₂ indicates Hf[OC₄H₉]₂[OC₂H₄N(CH₃)₂]₂ and Hf(OtBu)₂(mmp)₂ also indicates Hf[OC₄H₉]₂[OC₄H₈OCH₃]₂. Still further, tetrakis triethylsiloxy hafnium indicates Hf[Osi(C₂H₅)₃]₄ and Hf(OEt)₄ indicates Hf[OC₂H₅]₄. Hf(OiPr)₄ indicates Hf[OC₃H₇]₄ and Hf(OnBu)₄ also indicates Hf[OC₄H₉]₄. Hf(OtAm)₄ indicates Hf[OC₅H₁₁]₄.

Another example of a source is a precursor compound of a metal alkoxide, including any one or more of tantalum (Ta), aluminum (Al), silicon (Si), lanthanum (La), yttrium (Y), zirconium (Zr), magnesium (Mg), strontium (Sr), lead (Pb), titanium (Ti), niobium (Nb), cerium (Ce), ruthenium (Ru), barium (Ba), calcium (Ca), Indium (In), germanium (Ge), tin (Sn), vanadium (V), arsenic (As), praseodymium (Pr), antimony (Sb) and/or phosphorous (P).

Examples of a metal alkoxide include a 2-group metal alkoxide, a 3-group metal alkoxide, a 4-group metal alkoxide and/or a 5-group metal alkoxide. The 2-group metal alkoxide may include any one metal in a second group of the periodic table, such as magnesium (Mg), calcium (Ca) and/or strontium (Sr). The 3-group metal alkoxide includes any one or more metal in a third group of the periodic table, such as boron (B), aluminum (Al) and lanthanum (La). The 4-group metal alkoxide includes any one or more metal in a fourth group of the periodic table, such as titanium (Ti), zirconium (Zr), silicon (Si), germanium (Ge), tin (Sn) and/or lead (Pb). The 5-group metal alkoxide includes any one or more metal in a fifth group of the periodic table, such as vanadium (V), niobium (Nb), tantalum (Ta), phosphorous (P), arsenic (As) and/or antimony (Sb). As an exemplary embodiment of the present invention, the 4-group metal alkoxide may be selected as the metal alkoxide.

An example of magnesium alkoxide includes Mg[OC₂H₄OCH₃]₂ and an example of calcium alkoxide includes Ca[OC₂H₄OCH₃]₂. An example of strontium alkoxide includes Sr[OC₂H₄OCH₃]₂. Further, examples of boron alkoxide include B[OCH₃]₃, B[OC₂H₅]₃, B[OC₃H₇]₃, and B[OC₄H₉]₃. Examples of aluminum alkoxide include Al[OCH₃]₃, Al[OC₂H₅]₃, Al[OC₃H₇]₃, Al[OC₄H₉]₃ and Al[OC₄H₈OCH₃]₃. Examples of lanthanum alkoxide include La[OC₂H₄OCH₃]₃ and La[OC₃H₇CH₂OC₃H₇]₃.

Examples of titanium alkoxide include Ti[OCH₃]₄, Ti[OC₂H₅]₄, Ti[OC₃H₇]₄, Ti[OC₄H₉]₄ and Ti[OC₂H₅]₂[OC₂H₄N(CH₃)₂]₂. Examples of zirconium alkoxide include Zr[OC₃H₇]₄, Zr[OC₄H₉]₄, and Zr[OC₄H₈OCH₃]₄. Examples of silicon alkoxide include Si[OCH₃]₄, Si[OC₂H₅]₄, Si[OC₃H₇]₄, Si[OC₄H₉]₄, HSi[OCH₃]₃, HSi[OC₂H₅]₃, Si[OCH₃]₃F, Si[OC₂H₅]₃F, Si[OC₃H₇]₃F and Si[OC₄H₉]₃F. Examples of germanium alkoxide include Ge[OCH₃]₄, Ge[OC₂H₅]₄, Ge[OC₃H₇]₄ and Ge[OC₄H₉]₄. Examples of tin alkoxide include Sn[OC₄H₉]₄ and Sn[OC₃H₇]₃[C₄H₉]. Examples of lead alkoxide include Pb[OC₄H₉]₄ and Pb₄O[OC₄H₉]₆. Examples of vanadium alkoxide include VO[OC₂H₅]₃ and VO[OC₃H₇]₃. Examples of niobium alkoxide include Nb[OCH₃]₅, Nb[OC₂H₅]₅, Nb[OC₃H₇]₅ and Nb[OC₄H₉]₅. Examples of tantalum alkoxide include Ta[OCH₃]₅, Ta[OC₂H₅]₅, Ta[OC₃H₇]₅, Ta[OC₄H₉]₅, Ta[OC₂H₅]₅[OC₂H₄N(CH₃)₂] and Ta[OC₂H₅]₄[CH₃COCHCOCH₃].

Examples of phosphorous alkoxide include P[OCH₃]₃, P[OC₂H₅]₃, P[OC₃H₇]₃, P[OC₄H₉]₃, PO[OCH₃]₃, PO[OC₂H₅]₃, PO[OC₃H₇]₃ and PO[OC₄H₉]₃. Examples of arsenic alkoxide include As[OCH₃]₃, As[OC₂H₅]₃, As[OC₃H₇]₃ and As[OC₄H₉]₃. Examples of the antimony alkoxide include Sb[OC₂H₅]₃, Sb[OC₃H₇]₃ and Sb[OC₄H₉]₃. As an exemplary embodiment of the present invention, the source reservoir 110 may include a liquid source 112 and a source vaporizer, such as a bubbler, may be installed to the source reservoir 110 for vaporizing the liquid source 112 into the gaseous source 114. Although the above exemplary embodiments show the liquid source contained in the source reservoir together with the gaseous source and the source vaporizer installed together with the source reservoir in a body, the liquid source may also be contained in an additional reservoir and an additional source vaporizer may be installed to the source reservoir, as would be known to those of skill in the art.

As shown in the embodiments of FIG. 3, the source charger 120 is connected to the source reservoir 110 and the source gas 114 passes through the source charger 120 to the charging vessel 130. The source charger 120 may include a charging line 123 and a charging valve 121. The charging line 123 shown in FIG. 3 is a pipeline that connects the source reservoir 110 to the charging vessel 130. The charging valve 121 may control the amount of the gaseous source passing through the charging line 123 so that the gaseous source may be charged into the charging vessel 130 at a predetermined pressure or a pressure greater than the predetermined pressure.

The charging vessel 130 in the embodiments of FIG. 3 is connected to the source charger 120 and the gaseous source is charged through the source charger 120 from the source reservoir 110. The charging vessel 130 may be disposed adjacent to the reactor 150 and the source supplier 140 may be positioned between the charging vessel 130 and the reactor 150. In other words, a supplying apparatus according to some embodiments of the present invention includes an additional charging vessel 130 adjacent to the reactor 150 besides the source reservoir 110. As such, inner absorption of the source may be reduced or even prevented. In addition, the charging vessel 130 may contain only the gaseous source and only the gaseous source may be supplied to the reactor 150. Therefore, the reactor 150 may not be contaminated by the liquid source, which may facilitate maintenance of the supplying apparatus even when the reactor 150 is opened.

In some embodiments of the present invention, the charging vessel 130 is sufficiently voluminous to contain more of the source than is needed for normal reaction in the reactor 150, so that the gaseous source may be supplied to the reactor 150 in sufficient quantity to perform the normal reaction in a relatively short time.

A minimum volume of the charging vessel 130 may be determined based on the following volume equation:
V=f×t×A/P×Sf,
wherein (V) indicates the volume of the charging vessel, (f) indicates the flow rate of the source, (t) indicates a supplying time of the source in a cycle of the ALD process, (A) indicates an atmospheric pressure and (P) indicates an internal pressure of the charging vessel and (Sf) indicates a safety factor. When TEMAH, having a partial pressure that is relatively low, is used as the source, the supplying time t generally needs to be relatively increased so as to supply the source to the reactor in a sufficient quantity to provide a good step coverage. The partial pressure of TEMAH is defined as a fractional pressure of TEMAH in a source mixture including TEMAH and other materials for carrying TEMAH. According to the above volume equation, the volume of the charging vessel increases in accordance with the increase of the supplying time of the source.

Assuming that the flow rate of TEMAH is 500 standard cubic centimeters per minute (sccm), the internal pressure of the charging vessel is 90 Torr, the safety factor is 2 and the supplying time is 3 seconds in a cycle of deposition by the ALD process, the volume of the charging vessel is calculated to be about 423 cc. That is, the charging vessel 130 in some embodiments under such conditions is provided a volume of at least about 423 cc.

When TMA, having a relatively high partial pressure, is used as the source, the supplying time t may be shorter than the time when TEMAH is used to sufficiently supply the source to the reactor. The partial pressure of TMA is defined as a fractional pressure of TMA in a source mixture including TMA and other materials for carrying TMA. According to the above volume equation, the volume of the charging vessel decreases in accordance with the decrease on the supplying time of the source.

Assuming that the flow rate of TMA is 500 standard cubic centimeters per minute (sccm), the internal pressure of the charging vessel is 90 Torr, the safety factor is 2 and the supplying time is 0.7 seconds in a cycle of the deposition by the ALD process, the volume of the charging vessel calculated by the above volume equation is about 99 cc. That is, the charging vessel 130 in some embodiments of the present invention under such conditions is provided at least a volume of 99 cc.

When a buffer size for the gaseous source is relatively small, as in the above TMA example, the charging volume may be provided by the charging line 123, without the need for an additional charging vessel 130. The conventional supplying line used in the ALD process has a volume of 30 cc per meter, so that a charging vessel of 99 cc may be replaced with a charging line having a length of 3.3 m for the above TMA example.

As illustrated by these examples, the volume of the charging volume/vessel is inversely proportional to the partial pressure of the source and is directly determined by the supplying time, which is dependent on the partial pressure of the source.

The source supplier 140 supplies the gaseous source in the charging vessel 130 to the reactor 150. For the embodiments of FIG. 3, the source supplier 140 includes a supplying line 143 and a supplying valve 141 installed on the supplying line 143. In some embodiments, the supplying line 143 is a pipeline that connects the charging vessel 130 to the reactor 150 and the supplying valve 141 controls the amount of the gaseous source passing through the supplying line 143 from the charging vessel 130. As a result the gaseous source may be supplied into the reactor 150 in a predetermined amount sufficient for the chemical reaction of the ALD process. The supplying valve 141 may be, for example, a pneumatic valve or a throttle valve. A controller 131 is configured to selectively activate the supplying valve 141 and the charging valve 121 to control a pressure of the gaseous source charge in the charging vessel 130 and to control an amount of the gaseous source supplied to the reactor 150. The charging vessel 130 may be charged to a desired internal pressure while the supplying valve 141 is closed.

The mono-atomic layer may be formed in the reactor 150 by the ALD process using the above-described supplying apparatus. However, the supplying apparatus may also be used as part of a chemical vapor deposition apparatus.

The supplying apparatus in some embodiments of the present invention further includes a purging member 132 that removes the gaseous source from the charging vessel 130. A residual source gas remaining in the charging vessel 130 after supplying the source gas in a specified time is generally dissociated into elements thereof by heat. The dissociated elements of the residual source gas may be an impurity source in a subsequent process using a different source gas. Therefore, the residual source gas in the charging vessel 130 may be pumped out after the reaction in the reactor 150.

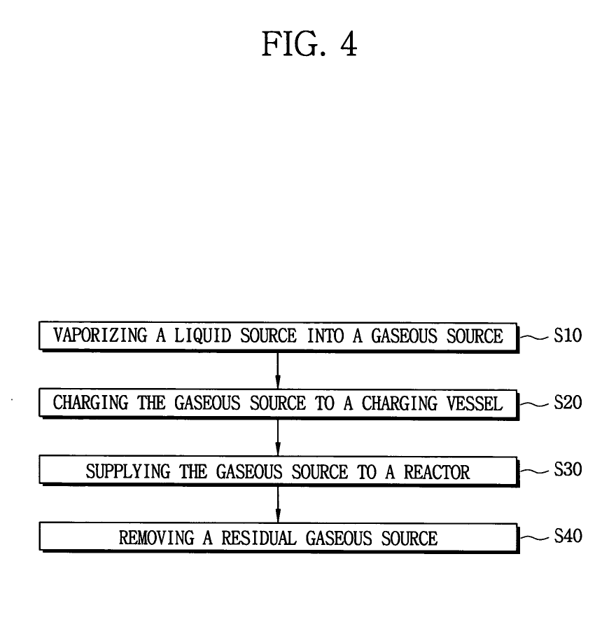

A method of supplying the source into the reactor using the above-mentioned supplying apparatus will now be described with reference to FIGS. 3 and 4. FIG. 4 is a flowchart illustrating a method of supplying the source according to some embodiments of the present invention. Referring now to FIG. 4, at block S10, the liquid source is initially vaporized into the gaseous source. For example, a bubbler may be used for vaporizing the liquid source. The bubbler may be integrally installed in the source reservoir in a body or may be installed external to the source reservoir.

At block S20, the gaseous source is charged into the charging vessel. The gaseous source may be charged into the charging vessel through the charging line 123 and the charging valve 121 may be used to control the interior pressure of the charging vessel, for example, in a range from about 90 to about 100 Torr. When the interior pressure of the charging vessel is below about 90 Torr, the source may not be sufficiently supplied in the specified (predetermined) time as a result of an insufficient pressure-gradient between the reactor and the charging vessel. When the interior pressure of the charging vessel is over about 100 Torr, the flow rate of the source gas may not be accurately controlled and, as a result, the supplied amount of the source gas may not be accurately controlled.

In some embodiments of the present invention, the charging vessel 130 is disposed adjacent to the reactor 150 and the source supplier 140 connects the charging vessel 130 to the reactor 150, so that the inner absorption of the source may be significantly reduced. In addition, the gaseous source may only be supplied to the reactor 150, as the charging vessel 130 may contain only the gaseous source. As a result, the reactor 150 may be prevented from being contaminated by the liquid source when the reactor is opened, which may reduce the maintenance cost for the ALD apparatus.

In some embodiments of the present invention, the charging vessel 130 is sufficiently voluminous to contain an amount of the source greater than is needed for a normal reaction in the reactor 150. As such, the gaseous source may be readily supplied to the reactor 150 in an amount and at a rate sufficient to perform a normal reaction in a relatively short time. The volume of the charging vessel may also be determined using the above provided volume equation, wherein the volume of the charging vessel is inversely proportional to the partial pressure of the source and is directly determined by the supplying time, which is dependent on the partial pressure of the source.

At block S30, the gaseous source may be supplied from the charging vessel 130 to the reactor 150 through the supplying line 143. The supplying valve 141 installed on the supplying line 143 may control the amount of the source. The supplying valve may be, for example, a pneumatic valve or a throttle valve.

At block S40, the residual source gas remaining in the charging vessel 130 after supplying the source gas is removed, for example, in a specified time. The residual gas in the charging vessel is generally dissociated into elements of the residual gas by heat. These dissociated elements of the residual source gas may be an impurity source in a subsequent process. Therefore, the residual source gas in the charging vessel 130 may be pumped out after the reaction in the reactor 150.

Although the above-mentioned method of supplying the source is particularly well suited to the ALD process for depositing an atomic layer, as the ALD process requires that the source gas be sufficiently supplied in a short time for good step coverage of the deposited layer, other depositing processes using a gaseous source may also be performed by the above-mentioned method of supplying the source, as will be understood by those of ordinary skill in the art.

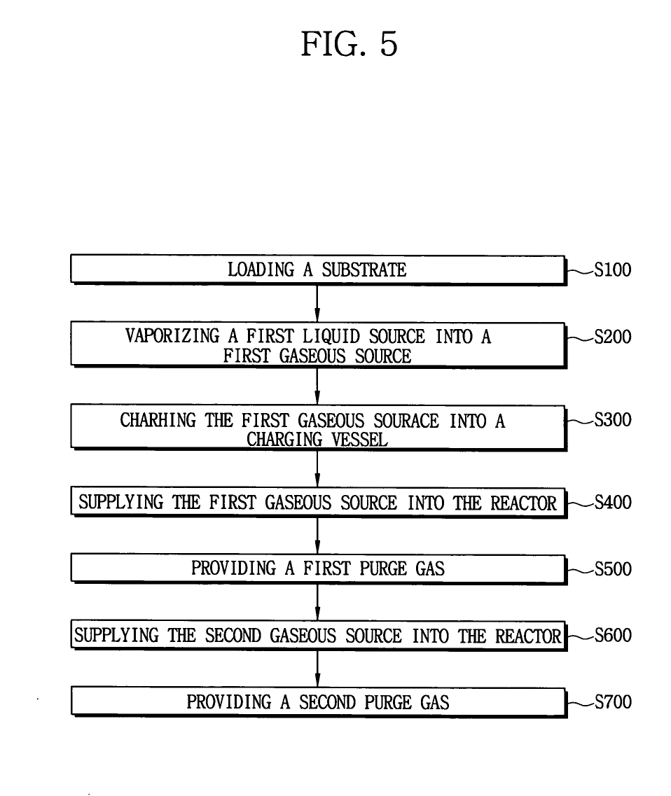

A method of depositing an atomic layer using the above-described method of supplying a source will now be described for some embodiments of the present invention with reference to FIGS. 3 and 5. FIG. 5 is a flowchart illustrating methods of depositing an atomic layer according to some embodiments of the present invention.

As shown in the embodiments of FIG. 5, At block S100, a substrate is loaded into the reactor 150. The substrate may include a silicon wafer having a lower layer structure, which may include various active devices. The reactor, 150 may include a processing reactor of an ALD apparatus or a processing chamber of a CVD apparatus. The substrate may be moved into the reactor 150 by using a substrate transporter, such as a robot arm.

At block 200, a first source in a liquid state is vaporized into a gaseous state. The first gaseous source is charged into the charging vessel 130 At block S300. The first gaseous source is charged into the charging vessel 130 through the charging line 123. The charging valve 121 may control the interior pressure of the charging vessel 130.

In some embodiments, the charging vessel 130 is disposed adjacent to the reactor 150 and the source supplier 140 connects the charging vessel 130 to the reactor 150, which may significantly reduce the inner absorption of the source. In addition, only the gaseous source may be supplied to the reactor 150, as the charging vessel 130 may contain only the first gaseous source. As a result, the reactor 150 may be prevented from being contaminated by the liquid source when the reactor is opened, which may reduce the maintenance cost of the ALD apparatus. In some embodiments, the charging vessel 130 has a sufficient volume to contain a quantity of the first source greater than is needed for a normal reaction in the reactor 150. As such, the first gaseous source may be sufficiently supplied to the reactor 150 so as to perform the normal reaction in a single process stop with a short process time. The volume of the charging vessel may be determined using the above volume equation, so that the volume of the charging vessel is inversely proportional to the partial pressure of the first source and is directly determined by the supplying time, which is dependent on the partial pressure of the first source.

For the embodiments of FIG. 5, At block S400, the first gaseous source is supplied from the charging vessel 130 to the reactor 150 through the supplying line 143 and is chemisorbed onto a surface of the substrate. In supplying the first gaseous source to the reactor 150, the supplying valve 141 disposed between the charging vessel 130 and the reactor 140 may be opened and the first gaseous source may be supplied to the reactor 150 at a high pressure in a short time.

At block S500, for the embodiments of FIG. 5, a first purge gas, including an inert gas, such as an argon (Ar) gas or a nitrogen (N₂) gas, is provided into the reactor 150 and the first gaseous source that is not chemisorbed is removed. At block S600, the second gaseous source is supplied to the reactor 150 and is chemisorbed on the substrate on which the first gaseous source is already chemisorbed.

The second source is generally selected based on the kind of layer formed on the substrate. For example, when a metal oxide layer is to be formed on a substrate, the second source may include, for example, ozone (O₃), oxygen (O₂), water (H₂O), hydrogen peroxide (H₂O₂), nitrous oxide (N₂O) and/or carbon dioxide (CO₂). The second source may also include ozone (O₃), oxygen (O₂), water (H₂O), hydrogen peroxide (H₂O₂), nitrous oxide (N₂O) and/or carbon dioxide (CO₂) that are activated by a plasma gas, a remote plasma gas and/or ultraviolet rays. When a nitride layer is to be formed on a substrate, the second source may include nitrous oxide (N₂O), ammonia (NH₃) and/or nitrogen (N₂). The second source may also include nitrous oxide (N₂O), ammonia (NH₃) and/or nitrogen (N₂) that are activated by a plasma gas, a remote plasma gas and/or ultraviolet rays.

For the embodiments of FIG. 5, at block S700, a second purge gas is provided into the reactor 150 and the second source that is not chemisorbed on the substrate is removed. The blocks S400 to S700 may be repeated multiple times so as to obtain a desired thickness of the layer. Block S200 of vaporizing the first source and block S300 of charging the first gaseous source may be carried out while block S500 of providing the first purge gas, block S600 of supplying the second gaseous source into the reactor and block S700 of providing the second purge gas are carried out. In other words, as the charging vessel may remain empty while blocks S500 to S700 are carried out, the source gas may be charged into the charging vessel at a high pressure. As a result, the source gas may be supplied to the reactor in a sufficient quantity in a short time and an additional time for charging the source gas to the charging vessel may avoid, so that the overall processing time for the ALD process may be reduced.

A residual source gas remaining in the charging vessel 130 after supplying the source gas over a given time may be dissociated into elements thereof by heat and the dissociated elements of the residual source gas may be an impurity source in a subsequent process. Therefore, the residual source gas in the charging vessel 130 may be pumped out after the reaction in the reactor 150.

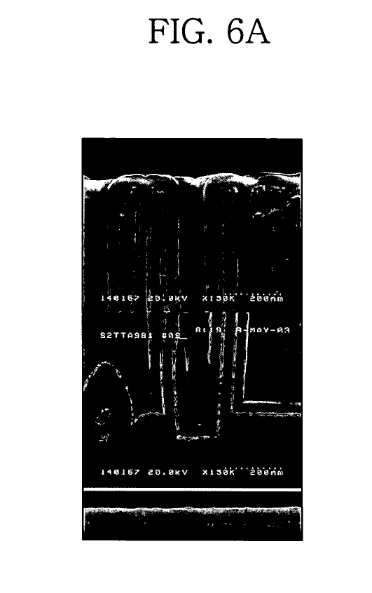

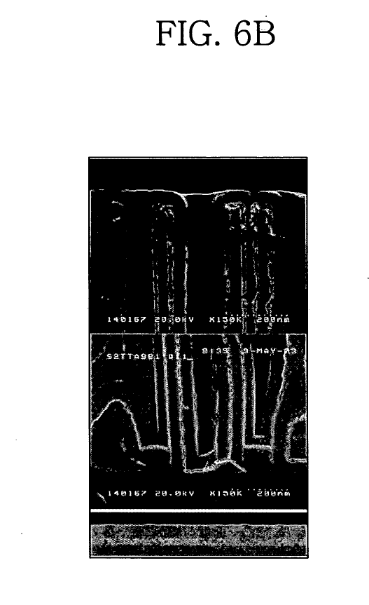

Two examples illustrating the effects of embodiments of the present invention will now be described. FIG. 6A is a picture illustrating a cross sectional surface of a hafnium oxide layer deposited under the conditions of Example 1. FIG. 6B is a picture illustrating a cross sectional surface of a hafnium oxide layer deposited under the conditions of Example 2.

### EXAMPLE 1

For Example 1, TEMAH is used as a first source and ozone (O₃) is used as a second source. The first source is supplied for 3 seconds at a flow rate of 500 sccm. A charging vessel is replaced with a supplying line corresponding to a volume of 423 cc without an additional charging vessel being installed. The source gases are charged into the supplying line for 0.4 second to a pressure of 90 Torr. As seen in FIG. 6A, an ALD process using the above conditions is performed to deposit a hafnium oxide layer having a step coverage of 0.41.

### EXAMPLE 2

For example 2, TEMAH is used as a first source and ozone (O₃) is used as a second source. The first source is supplied for 3 seconds at a flow rate of 500 sccm. The charging vessel is replaced with a supplying line corresponding to a volume of 423 cc without an additional charging vessel being installed. The source gases are charge into the supplying line for 1.2 second to a pressure of 100 Torr. As shown in FIG. 6B, an ALD process using the above conditions is performed to deposit a hafnium oxide layer having a step coverage of 0.51.

Examples 1 and 2 illustrate that the step coverage of the atomic layer deposited under the condition where the supplying time is 1.2 second is better than under the condition where the supplying time is 0.4 second. Thus, the above examples indicate that a large size charging vessel adjacent to the reactor may improve the step coverage of the deposited atomic layer.

According to some embodiments of the present invention, the source gas is sufficiently supplied to the reactor in a short time without increasing the supplying time or temperature of the source gas, so that the layer may be formed to have a good step coverage. In addition, the charging vessel may be installed adjacent to the reactor so that contamination of the supplying line may be reduced or even prevented, which may facilitate maintenance of the apparatus. Furthermore, the source gas may be charged into the charging vessel while the source gas is not supplied to the reactor, so that an additional charging time for charging the source gas may not be required, thereby reducing the overall processing time. As a result, the atomic layer may be more efficiently formed and the productivity of the ALD apparatus may be significantly increased, which may increase the yield of the semiconductor devices being produced using the apparatus.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. An apparatus for supplying a source, comprising:
a charging volume;
a source supplier configured to selectively couple the charging volume to a deposition process reactor; and
a source charger configured to selectively couple the charging volume to a gaseous source.

2. The apparatus of claim 1, further comprising a source reservoir configured to hold the gaseous source.

3. The apparatus of claim 2 wherein the source has a gaseous state and a liquid state and wherein the source reservoir includes a source vaporizer that vaporizes the source from the liquid state to the gaseous state to provide the gaseous source.

4. The apparatus of claim 3 wherein the source vaporizer comprises a bubbler.

5. The apparatus of Clam 3 wherein the source reservoir includes a liquid reservoir for source in the liquid state and a gaseous reservoir for source in the gaseous state.

6. The apparatus of claim 2 wherein the charging volume comprises a charging line having a volume selected based on a type of the source and a process to be performed in the deposition process reactor.

7. The apparatus of claim 2 wherein the charging volume comprises a charging vessel positioned proximate the deposition process reactor.

8. The apparatus of claim 2, wherein the source comprises a precursor compound of metal alkoxide, the metal alkoxide including at least one of hafnium (Hf), tantalum (Ta), aluminum (Al), silicon (Si), lanthanum (La), yttrium (Y), zirconium (Zr), magnesium (Mg), strontium (Sr), lead (Pb), titanium (Ti), niobium (Nb), cerium (Ce), ruthenium (Ru), barium (Ba), calcium (Ca), Indium (In), germanium (Ge), tin (Sn), vanadium (V), arsenic (As), praseodymium (Pr), antimony (Sb) and/or phosphorous (P).

9. The apparatus of claim 2, wherein the source includes at least one of tetrakis ethylmethylamino hafnium (TEMAH), Hf(OEt)₄, Hf(OPr)₃, Hf(OBu)₄, tetra n-butoxy hafnium (Hf(OnBu)₄), tetra tert-butoxy hafnium (Hf(OtBu)₄), Tetrakis-(mmp) hafnium (Hf(mmp)₄), Hf(OtBu)₂(dmae)₂ and/or Hf(OtBu)₂(mmp)₂,
wherein ‘dmae’ indicates dimethylaminoethoxide (—OC₂H₄N(CH₃)₂) and ‘mmp’ indicates 1-methoxy-2-methyl-2propoxy (—OC₄H₈OCH₃).

10. The apparatus of claim 2, wherein the source charger comprises:
a charging line connecting the source reservoir and the charging volume;
a charging valve coupled to the charging line and having an open state allowing source to flow from the source reservoir to the charging volume and a closed state restricting flow of source from the source reservoir to the charging volume; and
a controller configured to selectively activate the charging valve to control a pressure of the gaseous source charged into the charging vessel.

11. The apparatus of claim 10, wherein the charging valve comprises a pneumatic valve or a throttle valve.

12. The apparatus of claim 2, wherein the deposition process reactor comprises an atomic layer deposition (ALD) process reactor.

13. The apparatus of claim 2, wherein the charging volume has a size selected to be inversely proportional to a partial pressure of the source and wherein the partial pressure of the source is defined as a fractional pressure of the source in a source mixture including the source.

14. The apparatus of claim 2, wherein the source supplier comprises:
a supplying line that connects the charging volume to the reactor;
a supplying valve coupled to the charging volume and having an open state allowing source to flow from the charging volume to the reactor and a closed state restricting flow of source from the charging volume to the reactor; and
a controller configured to selectively activate the supplying valve to control an amount of the source supplied to the reactor through the supplying line.

15. The apparatus of claim 14, wherein the supplying valve comprises a pneumatic valve or a throttle valve.

16. The apparatus of claim 14, wherein the source charger comprises:
a charging line connecting the source reservoir and the charging volume;
a charging valve coupled to the charging line and having an open state allowing source to flow from the source reservoir to the charging volume and a closed state restricting flow of source from the source reservoir to the charging volume; and
a controller configured to selectively activate the charging valve to control a pressure of the gaseous source charged into the charging vessel.

17. The apparatus of claim 16 wherein the controller is configured to charge the gaseous source into the charging volume to a desired pressure while the supplying valve is closed.

18. The apparatus of claim 2, wherein deposition process reactor comprises a chemical vapor deposition (CVD) process reactor.

19. The apparatus of claim 2, further comprising a purging member configured to purge a residual source remaining in the charging volume.

20. A method of supplying a source to a reactor, the method comprising:
charging a gaseous source into a charging volume by selectively activating a source charger coupled between the charging volume and a source reservoir; and then
supplying the gaseous source from the charging volume into a deposition process reactor by selectively activating a source supplier coupled between the charging volume and the reactor after the gaseous source in the charging volume attains a desired internal pressure.

21. The method of claim 20, wherein the desired internal pressure of the charging volume is between about 90 Torr and about 100 Torr.

22. The method of claim 20, wherein supplying the gaseous source is followed by removing a residual gaseous source remaining in the charging volume after supplying the gaseous source to the reactor.

23. The method of claim 20, wherein the source comprises a precursor compound of metal alkoxide, the metal alkoxide including at least one of hafnium (Hf), tantalum (Ta), aluminum (Al), silicon (Si), lanthanum (La), yttrium (Y), zirconium (Zr), magnesium (Mg), strontium (Sr), lead (Pb), titanium (Ti), niobium (Nb), cerium (Ce), ruthenium (Ru), barium (Ba), calcium (Ca), Indium (In), germanium (Ge), tin (Sn), vanadium (V), arsenic (As), praseodymium (Pr), antimony (Sb) and/or phosphorous (P).

24. The method of claim 20, wherein the source includes at least one of tetrakis ethylmethylamino hafnium (TEMAH), Hf(OEt)₄, Hf(OPr)₃, Hf(OBu)₄, tetra n-butoxy hafnium (Hf(OnBu)₄), tetra tert-butoxy hafnium (Hf(OtBu)₄), Tetrakis-(mmp) hafnium (Hf(mmp)₄), Hf(OtBu)₂(dmae)₂ and/or Hf(OtBu)₂(mmp)₂, wherein ‘dmae’ indicates dimethylaminoethoxide (—OC₂H₄N(CH₃)₂) and ‘mmp’ indicates, 1-methoxy-2-methyl-2propoxy (—OC₄H₈OCH₃).

25. A method of depositing an atomic layer, comprising:
loading a substrate into an atomic layer deposition (ALD) process reactor;
charging a first gaseous source into a charging volume;
supplying the first gaseous source into the reactor from the charging volume so that the first gaseous source is chemisorbed onto a surface of the substrate;
providing a first purge gas into the reactor so that a portion of the first source that is not chemisorbed onto the surface of the substrate is removed from the reactor;
supplying a second source into the reactor so that the second source is chemisorbed onto the surface of the substrate including the first source; and
providing a second purge gas into the reactor so that a portion of the second source that is not chemisorbed onto the surface of the substrate is removed from the reactor.

26. The method of claim 25 wherein charging a first gaseous source comprises charging the first gaseous source until the charging volume attains a desired internal pressure.

27. The method of claim 26, wherein the desired internal pressure of the charging volume is between about 90 Torr and about 100 Torr.

28. The method of claim 25 wherein charging a first gaseous source is preceded by vaporizing a first source in a liquid state into a first source in a gaseous state to provide the first gaseous source.

29. The method of claim 28 further comprising:
repeating supplying the first gaseous source into the reactor, providing a first purge gas into the reactor, supplying a second source into the reactor and providing a second purge gas into the reactor; and
wherein vaporizing a first source and charging a first gaseous source into a charging volume are carried out while providing a first purge gas into the reactor, supplying a second source into the reactor and/or providing a second purge gas into the reactor.

30. The method of claim 29, wherein the first and second purge gases comprise argon (Ar) gas and/or nitrogen (N₂) gas.

31. The method of claim 28, wherein the second source comprises at least one of ozone (O₃), oxygen (O₂), water (H₂O), hydrogen peroxide (H₂O₂), nitrous oxide (N₂O), carbon dioxide (CO₂), ammonia (NH₃), nitrogen (N₂), and/or ozone (O₃), oxygen (O₂), water (H₂O), hydrogen peroxide (H₂O₂), nitrous oxide (N₂O), carbon dioxide (CO₂), ammonia (NH₃), and/or nitrogen (N₂) that are activated by a plasma gas, a remote plasma gas and/or ultraviolet rays.
